(19) United States
(12) Patent Application Publication
(10) Pub. No.: US 2025/0357906 A1
(43) Pub. Date: Nov. 20, 2025

(54) RADIO FREQUENCY POWER AMPLIFIER

(71) Applicant: Murata Manufacturing Co., Ltd., Nagaokakyo-shi (JP)

(72) Inventor: Kiichiro TAKENAKA, Nagaokakyo-shi (JP)

(21) Appl. No.: 19/208,660

(22) Filed: May 15, 2025

(30) Foreign Application Priority Data
May 15, 2024 (JP) 2024-079550

(51) Int. Cl. H03F 3/60; H03F 1/56; H03F 3/24

(52) U.S. Cl. CPC H03F 3/602; H03F 1/56; H03F 3/245; H03F 3/605; H03F 2200/198; H03F 2200/451

(57) ABSTRACT

A hybrid coupler has a first port, a second port, a third port, and a fourth port to which a load is connected. An input signal distributor distributes a first input signal that is a radio frequency signal into a second input signal and a third input signal. The second input signal is inputted to a balanced amplifier. The balanced amplifier outputs two amplified radio frequency signals with a phase difference of 90° from each other from two output ends, one of which is coupled to the first port and another one of which is coupled to the second port. The control amplifier amplifies the third input signal and outputs the amplified third input signal from an output end. The output end of the control amplifier is coupled to the third port without any circuit component affecting impedance matching disposed in between.

### CROSS REFERENCE TO RELATED APPLICATION

This application claims priority from Japanese Patent Application No. 2024-079550 filed on May 15, 2024. The content of this application is incorporated herein by reference in its entirety.

### BACKGROUND OF THE DISCLOSURE

### 1. Field of the Disclosure

The present disclosure relates to a radio frequency power amplifier.

### 2. Description of the Related Art

Load-modulated balanced amplifiers (LMBAs) are attracting attention as a technology for providing high-efficiency radio frequency power amplifiers (disclosed in K. Takenaka, et al., “Load-Modulated Balanced Amplifier Design for Handset Applications”, IEEE Microwave and Wireless Technology Letters, Vol. 33, No. 6, June 2023). In the disclosed LMBA, the balanced amplifier is class AB biased and the control amplifier for modulating the load impedance of the balanced amplifier is class C biased. The two radio frequency signals with a 90° phase difference outputted from the balanced amplifier and the radio frequency signal outputted from the control amplifier are combined by the hybrid coupler and are supplied to the load.

### BRIEF SUMMARY OF THE DISCLOSURE

In the disclosed LMBA, an impedance matching circuit is inserted between the control amplifier and the hybrid coupler to operate the balanced amplifier and the control amplifier at high power-added efficiency with a single power supply. This impedance matching circuit is a factor that hinders the miniaturization of the device and the wider bandwidth of a radio frequency amplifier.

It is a possible benefit of the present disclosure to provide a radio frequency power amplifier with which the miniaturization of a device and the wider bandwidth of the radio frequency power amplifier can be achieved.

According to an aspect of the present disclosure, there is provided a radio frequency power amplifier including a hybrid coupler having a first port, a second port, a third port, and a fourth port to which a load is connected, an input signal distributor configured to distribute a first input signal that is a radio frequency signal into a second input signal and a third input signal, a balanced amplifier configured to receive the second input signal and output two amplified radio frequency signals with a phase difference of 90° from each other from two output ends, one of which is coupled to the first port and another one of which is coupled to the second port, and a control amplifier configured to amplify the third input signal and output the amplified third input signal from an output end that is coupled to the third port without any circuit component affecting impedance matching disposed in between. A power supply voltage in common is supplied to the balanced amplifier and the control amplifier. A voltage level of the first input signal at a rise of a current outputted from the control amplifier is higher than a voltage level of the first input signal at a rise of a current outputted from the balanced amplifier. The hybrid coupler changes a load impedance of the balanced amplifier coupled to the first port and the second port in accordance with a current level of a radio frequency signal inputted to the third port from the control amplifier.

Since the output end of the balanced amplifier is coupled to the third port of the hybrid circuit without any circuit component affecting impedance matching disposed in between, the miniaturization of the device can be achieved. Furthermore, degradation of broadband characteristics due to insertion of an impedance matching circuit is suppressed.

### BRIEF DESCRIPTION OF THE SEVERAL VIEWS OF THE DRAWINGS

FIG. 1 is a block diagram of a radio frequency power amplifier according to a first embodiment;

FIG. 2 is a schematic equivalent circuit diagram illustrating the operation of a hybrid coupler;

FIG. 3 is a block diagram of a radio frequency power amplifier according to a comparative example;

FIG. 4A is a graph illustrating the relationships between the input voltage of a first input signal (FIG. 3) and currents;

FIG. 4B is a graph illustrating the relationships between the input voltage of the first input signal and voltages;

FIG. 4C is a graph illustrating the relationships between the input voltage and load impedances;

FIG. 5A is a graph illustrating the relationships between the input voltage of the first input signal (FIG. 1) and the currents;

FIG. 5B is a graph illustrating the relationships between the input voltage of the first input signal and the voltages;

FIG. 5C is a graph illustrating the relationships between the input voltage of the first input signal and the load impedances;

FIG. 6 is a graph illustrating the relationships between the input voltage of the first input signal and the voltages when the rising point of the current is changed in the radio frequency power amplifier according to the first embodiment;

FIG. 7 is a graph illustrating the relationships between the input voltage of the radio frequency power amplifier according to the first embodiment and power-added efficiency;

FIG. 8 is a schematic plan view of a hybrid coupler used in a radio frequency power amplifier according to a modification of the first embodiment;

FIG. 9 is a schematic perspective view of a hybrid coupler used in a radio frequency power amplifier according to another modification of the first embodiment;

FIG. 10 is an equivalent circuit diagram of a hybrid coupler used in a radio frequency power amplifier according to still another modification of the first embodiment;

FIG. 11 is a block diagram of a radio frequency power amplifier according to a second embodiment;

FIG. 12 is a block diagram of a radio frequency power amplifier according to a third embodiment;

FIG. 13 is a block diagram of a radio frequency power amplifier according to a fourth embodiment; and

FIG. 14 is a block diagram of a communication device according to a fifth embodiment.

### DETAILED DESCRIPTION OF THE DISCLOSURE

### First Embodiment

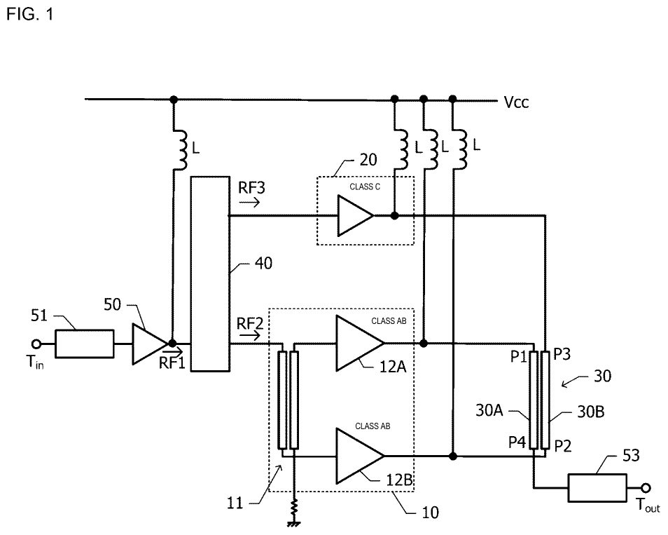

A radio frequency power amplifier according to a first embodiment will be described with reference to FIGS. 1 to 5C.

FIG. 1 is a block diagram of a radio frequency power amplifier according to the first embodiment. The radio frequency power amplifier according to the first embodiment includes a balanced amplifier 10, a control amplifier 20, a hybrid coupler 30, and an input signal distributor 40. The radio frequency power amplifier according to the first embodiment and a peripheral circuit will be described below.

A radio frequency signal inputted from an input terminal Tᵢₙ is inputted to a drive stage amplifier 50 via an impedance matching circuit 51. This radio frequency signal is a signal in a radio frequency band modulated by a predetermined communication method. A power supply voltage Vcc is supplied to the drive stage amplifier 50 via a choke coil L. The drive stage amplifier 50 amplifies an input radio frequency signal to output a first input signal RF1. The first input signal RF1 amplified by the drive stage amplifier 50 is inputted to the input signal distributor 40.

The input signal distributor 40 distributes the first input signal RF1 to output a second input signal RF2 and a third input signal RF3. As the input signal distributor 40, for example, a 3-dB coupler using a coupling transmission line or a Wilkinson distributor can be used. For example, the respective signal levels of the second input signal RF2 and RF3 are 3 dB down from the signal level of the first input signal RF1, and they have a phase difference of 90°. The respective signal levels of the second input signal RF2 and the third input signal RF3 and the phase difference between them may be other values. The second input signal RF2 is inputted to the balanced amplifier 10, and the third input signal RF3 is inputted to the control amplifier 20.

The balanced amplifier 10 includes two amplifiers 12A and 12B that amplify the two respective radio frequency signals obtained by distributing the second input signal RF2. The amplifiers 12A and 12B are formed of, for example, heterojunction bipolar transistors (HBTs). For example, a distributor 11 distributes the second input signal RF2 into two radio frequency signals. The signal levels of the two radio frequency signals are equal, and they have a phase difference of 90°. As the distributor 11, for example, a 3-dB coupler using a coupling transmission line can be used. Each of the amplifiers 12A and 12B is given a class AB bias. The power supply voltage Vcc is supplied to each of the amplifiers 12A and 12B via the choke coil L.

The control amplifier 20 is given a class C bias and amplifies the third input signal RF3. The control amplifier 20 is formed of, for example, a heterojunction bipolar transistor (HBT). The power supply voltage Vcc is supplied to the control amplifier 20 via the choke coil L. That is, the balanced amplifier 10 and the control amplifier 20 operate with the single power supply voltage Vcc.

The hybrid coupler 30 includes a main line 30A and a sub line 30B that are electromagnetically coupled to each other. One end of the main line is referred to as a first port P1, and the other end is referred to as a fourth port P4. An end portion of the sub line on the first port P1 side is referred to as a third port P3, and an end portion of the sub line on the fourth port P4 side is referred to as a second port P2.

The output ends of the two amplifiers 12A and 12B are coupled to the first port P1 and the second port P2 of the hybrid coupler 30, respectively. The output end of the control amplifier 20 is coupled to the third port of the hybrid coupler 30. The fourth port P4 of the hybrid coupler 30 is coupled to an output terminal Tout via an impedance matching circuit 53. The output terminal Tout is connected to a load, such as an antenna.

Radio frequency signals inputted to the first port P1 and the second port P2 are combined and outputted from the fourth port P4. A radio frequency signal inputted to the third port P3 is outputted from the fourth port P4. That is, a radio frequency signal with power equal to the sum of the powers of radio frequency signals inputted to the first port P1, the second port P2, and the third port P3 is outputted from the fourth port P4. The load impedances of the two amplifiers 12A and 12B in the balanced amplifier 10 change in accordance with the current level of a radio frequency signal inputted from the control amplifier 20 to the third port P3. More specifically, the respective load impedances of the two amplifiers 12A and 12B in the balanced amplifier 10 change in accordance with the ratio between the current level of a radio frequency signal inputted from the control amplifier 20 to the third port P3 and corresponding one of the current levels of radio frequency signals inputted from the balanced amplifier 10 to the first port P1 and the second port P2.

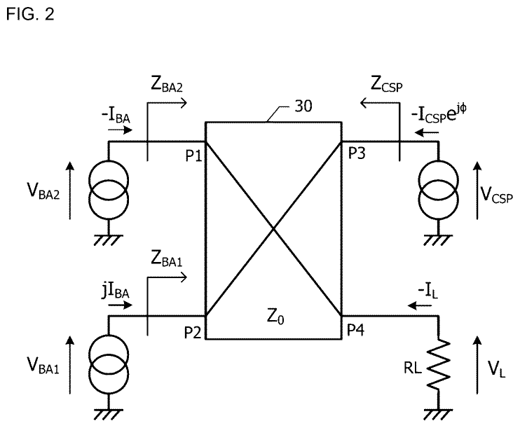

Next, the operation of the hybrid coupler 30 will be described in more detail with reference to FIG. 2. FIG. 2 is a schematic equivalent circuit diagram illustrating the operation of the hybrid coupler 30. It is assumed that current sources for allowing currents −I_{BA}, jI_{BA}, and −I_{CSP}e^{jφ} to flow are connected to the first port P1, the second port P2, and the third port P3, respectively. The current sources connected to the first port P1, the second port P2, and the third port P3 correspond to the amplifiers 12A and 12B in the balanced amplifier 10 and the control amplifier 20 (FIG. 1), respectively. Here, j represents an imaginary unit and φ represents a phase offset.

A load RL is connected to the fourth port P4. The current flowing to the fourth port P4 from the load RL is represented as −I_{L}. The voltages generated at the first port P1, the second port P2, the third port P3, and the fourth port P4 are represented as V_{BA2}, V_{BA1}, V_{CSP}, and V_{L}, respectively. The load impedances on the load side when viewed from the first port P1, the second port P2, and the third port P3 are represented as Z_{BA2}, Z_{BA1}, and Z_{CSP}, respectively.

The current flowing to the hybrid coupler 30 and the voltages generated at the respective ports are expressed by the following relational expressions using the impedance matrix of the hybrid coupler 30.

$$( \begin{matrix}{V}_{L} \\ {V}_{B A 1} \\ {V}_{CSP} \\ {V}_{B A 2}\end{matrix} ) = {Z}_{0} ( \begin{matrix}0 & 0 & - j & - j \sqrt{2} \\ 0 & 0 & - j \sqrt{2} & - j \\ - j & - j \sqrt{2} & 0 & 0 \\ - j \sqrt{2} & - j & 0 & 0\end{matrix} ) ( \begin{matrix}- {I}_{L} \\ {jI}_{BA} \\ - {I}_{CSP} {e}^{j ϕ} \\ - {I}_{BA}\end{matrix} ) \qquad ( 1 )$$

where Z₀ represents the characteristic impedance of the hybrid coupler 30.

When Expression (1) is expanded, the load impedances Z_{BA1} and Z_{BA2} are expressed by the following expressions.

$${Z}_{B A 1} = {Z}_{B A 2} = {Z}_{0} ( 1 + \sqrt{2} \frac{{I}_{CSP}}{{I}_{BA}} {e}^{j ϕ} ) \qquad ( 2 )$$

The load impedance Z_{CSP} is expressed by the following expression.

$${Z}_{CSP} = {Z}_{0} \qquad ( 3 )$$

The voltages V_{BA1} and V_{BA2} are expressed by the following expression.

$${V}_{BA 1} = {V}_{B A 2} = {Z}_{B A 1} {I}_{B A} = {Z}_{BA 2} {I}_{B A} = {Z}_{0} ( {I}_{BA} - \sqrt{2} {I}_{CSP} ) \qquad ( 4 )$$

It is apparent from Expression (2) that the load impedances Z_{BA1} and Z_{BA2} are equal and are controlled by the current I_{CSP} inputted to the third port P3 and the phase offset φ. On the other hand, the load impedance Z_{CSP} on the load side when viewed from the third port P3 is constant.

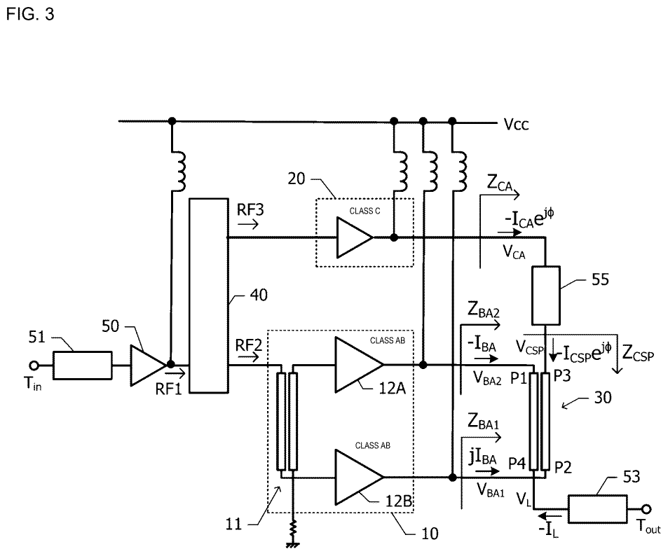

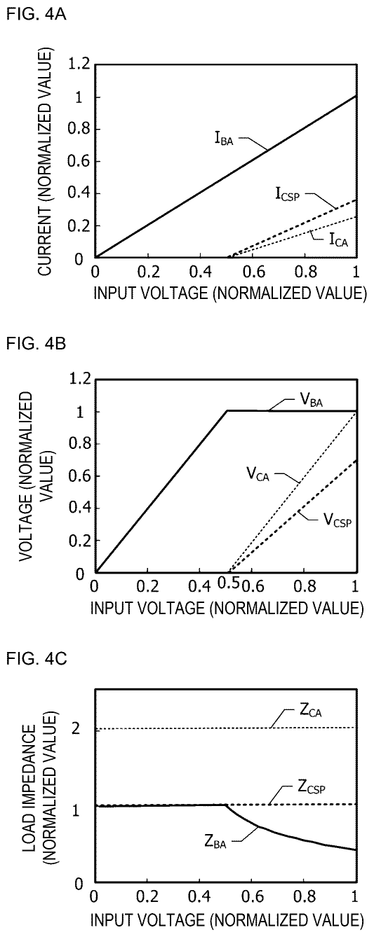

Next, a radio frequency power amplifier according to a comparative example and the operation of the radio frequency power amplifier will be described with reference to FIGS. 3 to 4C.

FIG. 3 is a block diagram of the radio frequency power amplifier according to the comparative example. In the radio frequency power amplifier according to the first embodiment (FIG. 1), the output end of the control amplifier 20 and the third port P3 of the hybrid coupler 30 are directly connected to each other. However, in the comparative example, an impedance matching circuit 55 is inserted between them.

The currents and the voltages at the respective ports of the hybrid coupler 30 are represented in the same manner as the currents and the voltages illustrated in FIG. 2. The load impedance on the load side when viewed from the output end of the control amplifier 20 is represented as Z_{CA}. The current outputted from the control amplifier 20 is represented as −I_{CA}e^{jφ}, and the voltage at the output end of the control amplifier 20 is represented as V_{CA}.

FIG. 4A is a graph illustrating the relationships between the input voltage of the first input signal RF1 (FIG. 3) and the currents I_{BA}, I_{CSP}, and I_{CA}. FIG. 4B is a graph illustrating the relationships between the input voltage of the first input signal RF1 and the voltages V_{BA}, V_{CSP}, and V_{CA}. The horizontal axis in FIGS. 4A and 4B represents the input voltage, normalized by its maximum value. The vertical axis in FIG. 4A represents the current, normalized by the maximum value of the current I_{BA}. The vertical axis in FIG. 4B represents the voltage, normalized by the maximum value of the voltage V_{BA}.

Since the balanced amplifier 10 is given a class AB bias, the current I_{BA} rises from the point where the normalized value of the input voltage is zero and increases almost linearly as the input voltage rises as illustrated in FIG. 4A. When the normalized value of the input voltage reaches one, the normalized value of the current I_{BA} becomes one. Since the control amplifier 20 is given a class C bias, the current I_{CA} rises at a voltage level higher than the input voltage at which the current I_{BA} rises, for example, at the normalized input voltage of 0.5. At the same time as the current I_{CA} rises, the current I_{CSP} also rises. The currents I_{CSP} and I_{CA} increase linearly as the input voltage level rises.

When the slope of the current I_{CSP} is 2^{-1/2} times the slope of the current I_{BA}, the voltage V_{BA} becomes constant as illustrated in FIG. 4B (see Expression (4)). With this relationship, the balanced amplifier 10 can operate as a carrier amplifier for the Doherty amplifier.

To maximize the power-added efficiency of the radio frequency power amplifier, it is desirable that the voltages V_{BA} and V_{CA} match each other when the normalized value of the input voltage is one (i.e., the input voltage is the maximum value). FIG. 4B illustrates the state in which the voltages V_{BA} and V_{CA} match each other when the normalized value of the input voltage is one. In general, the current I_{CA} does not match the current I_{CSP} and the voltage V_{CSP} does not match the voltage V_{CA} at that time.

FIG. 4C is a graph illustrating the relationships between the input voltage and the load impedances Z_{BA}, Z_{CSP}, and Z_{CA}. The horizontal axis represents the input voltage as a normalized value, and the vertical axis represents the load impedance normalized by the characteristic impedance Z₀ of the hybrid coupler 30. In the range in which the current I_{CSP} is zero, the normalized value of the load impedance Z_{BA} is one (see Expression (2)). The normalized value of the load impedance Z_{CSP} is also one (see Expression (3)).

Since the currents I_{CSP} and I_{CA} do not match each other and the voltages V_{CSP} and V_{CA} do not match each other, the load impedances Z_{CA} and Z_{CSP} differ from each other. Accordingly, in the comparative example, the impedance matching circuit 55 (FIG. 3) needs to be inserted between the output end of the control amplifier 20 and the third port P3 of the hybrid coupler 30.

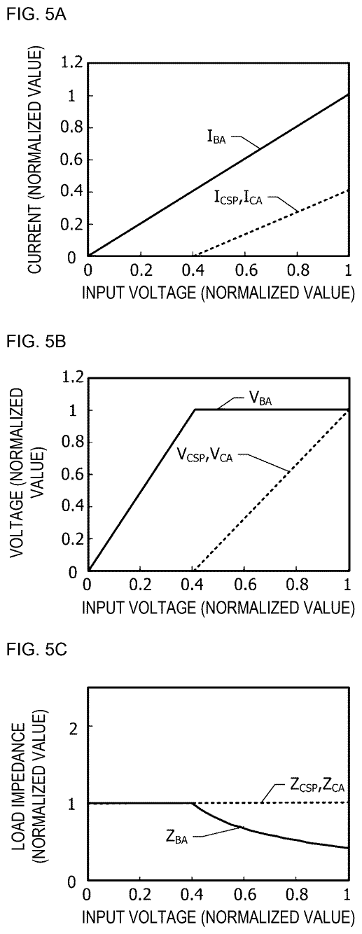

Next, the operation of the radio frequency power amplifier according to the first embodiment will be described with reference to FIGS. 5A, 5B, and 5C. FIG. 5A is a graph illustrating the relationships between the input voltage of the first input signal RF1 (FIG. 1) and the currents I_{BA}, I_{CSP}, and I_{CA}, FIG. 5B is a graph illustrating the relationships between the input voltage of the first input signal RF1 and the voltages V_{BA}, V_{CSP}, and V_{CA}, and FIG. 5C is a graph illustrating the relationships between the input voltage of the first input signal RF1 and the load impedances Z_{BA}, Z_{CSP}, and Z_{CA}.

In the comparative example (FIG. 4A), the normalized value of the input voltage at the rise of the current I_{CA} is set to 0.5. However, in the first example, the normalized value of the input voltage at the rise of the current I_{CA} is set to 0.4 (FIG. 5A). The current I_{CSP} also rises when the normalized value of the input voltage is 0.4. When the slope of the current I_{CA} is adjusted to be 2^{-1/2} times the slope of the current I_{BA} as well as the slope of the current I_{CSP}, the normalized value of the voltage V_{CA} reaches one when the normalized value of the input voltage is one (FIG. 5B). Since the currents I_{CSP} and I_{CA} match each other, the voltages V_{CSP} and V_{CA} also match each other.

Since the currents I_{CA} and I_{CSP} match each other and the voltages V_{CA} and V_{CSP} match each other, the load impedances Z_{CA} and Z_{CSP} match each other. Since both of them match each other, the impedance matching circuit 55 (FIG. 3) inserted in the comparative example is unnecessary in the first embodiment.

Next, the advantageous effect of the first embodiment will be described. In the first embodiment, under the conditions that the balanced amplifier 10 and the control amplifier 20 are driven with the single power supply voltage Vcc as illustrated in FIG. 2, the maximum value of the voltage V_{BA} at the output end of the balanced amplifier 10 and the maximum value of the voltage V_{CA} at the output end of the control amplifier 20 almost match each other as illustrated in FIG. 5B. Accordingly, when the input voltage is at its maximum value, the balanced amplifier 10 and the control amplifier 20 can be operated simultaneously at high efficiency.

Thus, high efficiency can be achieved without inserting an impedance matching circuit between the control amplifier 20 and the third port P3 of the hybrid coupler 30. Since there is no need to dispose an impedance matching circuit between the output end of the control amplifier 20 and the third port P3 of the hybrid coupler 30, the miniaturization of a device can be achieved. Furthermore, the degradation of broadband characteristics caused by an impedance matching circuit can be suppressed.

A radio frequency power amplifier according to a modification of the first embodiment will be described. In the first embodiment, no impedance matching circuit is inserted between the output end of control amplifier 20 and the third port P3 of the hybrid coupler 30 and the output end of the control amplifier 20 is directly connected to the third port P3 of the hybrid coupler 30 as illustrated in FIG. 1. Here, “directly connected” means that no circuit component that substantially affects the impedance of a radio frequency signal is connected. For example, as illustrated in FIG. 1, the choke coil L may be connected between the line connecting the output end of the control amplifier 20 and the third port P3 of the hybrid coupler 30 and a power supply line, which exhibits a virtually infinite impedance to a radio frequency signal. Furthermore, for example, a DC-cut capacitor that has virtually zero impedance to a radio frequency signal may be inserted between the output end of the control amplifier 20 and the third port P3 of the hybrid coupler 30.

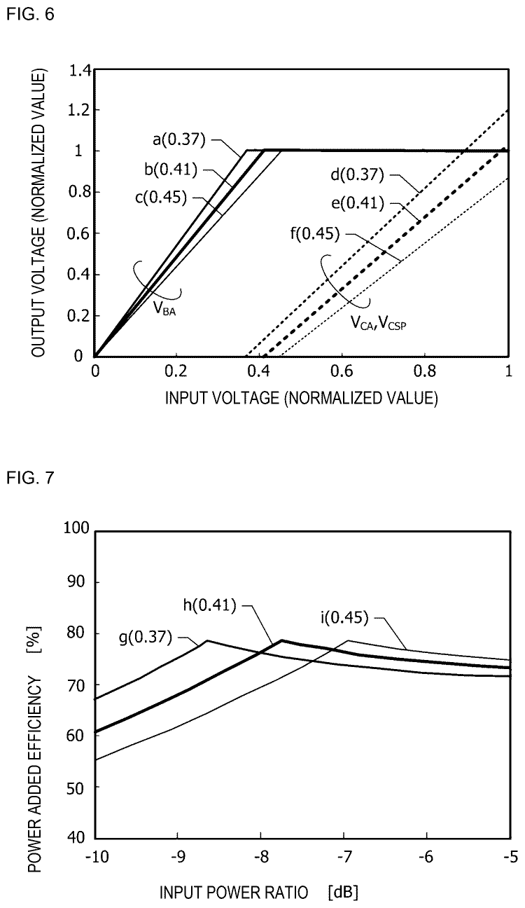

Next, a radio frequency power amplifier according to another modification of the first embodiment will be described with reference to FIGS. 6 and 7. In the first embodiment, as illustrated in FIG. 5B, to make the maximum value of the voltage V_{BA} at the output end of the balanced amplifier 10 nearly equal to the maximum value of the voltage V_{CA} at the output end of the control amplifier 20, the normalized value of an input voltage (the voltage level of the first input signal RF1 (FIG. 1)) when the current I_{CA} outputted from the control amplifier 20 rises (hereinafter sometimes referred to as a rising point) is set to approximately 0.4. In the modification to be described below, the preferred range of the rising point of the current I_{CA} will be described.

FIG. 6 is a graph illustrating the relationships between the input voltage of the first input signal RF1 and the voltages V_{BA}, V_{CSP}, and V_{CA} when the rising point of the current I_{CA} is changed. The horizontal and vertical axes are the same as the horizontal and vertical axes of the graph illustrated in FIG. 5B, respectively. Solid lines a, b, and c in the graph in FIG. 6 represent the voltages V_{BA} when the rising point of the current I_{CA} is set to 0.37, 0.41, and 0.45, respectively, and broken lines d, e, and f represent the voltages V_{CA} and V_{CSP} when the rising point of the current I_{CA} is set to 0.37, 0.41, and 0.45, respectively. In FIG. 6, numbers in parentheses attached to the solid and broken lines represent the rising points of the current I_{CA}.

When the rising point is set to 0.41, the maximum value of the voltage V_{BA} and the maximum value of the voltage V_{CA} are almost the same. High efficiency can therefore be obtained. When the rising point is set to 0.37 or 0.45, there is a difference between the maximum value of the voltage V_{BA} and the maximum value of the voltage V_{CA}. However, the difference is less than or equal to 20% of the voltage normalized value. This degree of difference is sufficient to maintain sufficiently high efficiency of the radio frequency power amplifier. Accordingly, to maintain the high efficiency of the radio frequency power amplifier, it is desirable that the rising point of the current I_{CA} be 0.37 or more and 0.45 or less.

To maintain higher efficiency of the radio frequency power amplifier, it is more desirable that the difference between the maximum value of the voltage V_{BA} and the maximum value of the voltage V_{CA} be less than or equal to 10% with respect to the voltage normalized value. To meet this requirement, it is more desirable to set the rising point of the current I_{CA} to 0.39 or more and 0.43 or less.

FIG. 7 is a graph illustrating the relationships between the input power of the radio frequency power amplifier according to the first embodiment and power-added efficiency. The horizontal axis represents the ratio of input power to the maximum value of input power in units [dB], and the vertical axis represents power-added efficiency in units [%]. Solid lines g, h, and i in the graph in FIG. 7 represent power-added efficiency when the rising point of the current I_{CA} is set to 0.37, 0.41, and 0.45, respectively. In FIG. 7, numbers in parentheses attached to the solid lines represent the rising points of the current I_{CA}.

It is apparent that the input power ratio at which the power-added efficiency peaks differs depending on the rising point of the current I_{CA}. For example, in the range in which the input power ratio is less than or equal to approximately −8.5 dB, higher efficiency is obtained when the rising point of the current I_{CA} is set to 0.37, as compared with when it is set to the other values. In the range in which the input power ratio is greater than or equal to approximately −7 dB, higher efficiency is obtained when the rising point of the current I_{CA} is set to 0.45, as compared with when it is set to the other values. In the range in which the input power ratio is approximately −8.5 dB or more and approximately −7 dB or less, higher efficiency is obtained when the rising point of the current I_{CA} is set to 0.41, as compared with when it is set to the other values.

Thus, changing the rising point of the current I_{CA} changes the range of the input power ratio in which high efficiency can be obtained.

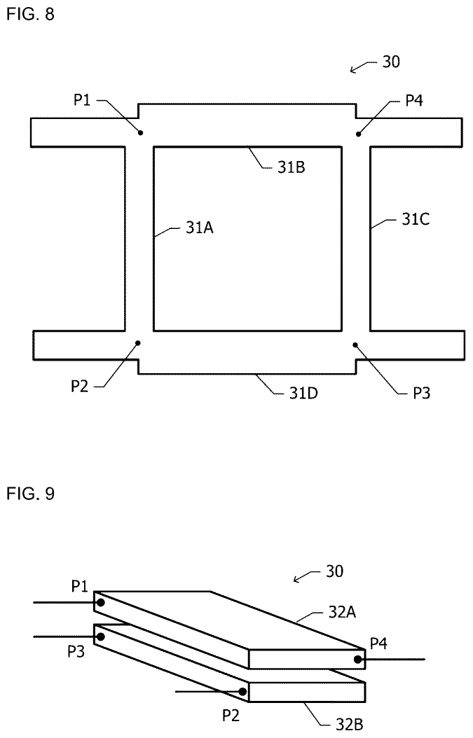

Next, a radio frequency power amplifier according to still another modification of the first embodiment will be described with reference to FIGS. 8, 9, and 10. In the first embodiment, a 3-dB coupler including a coupling transmission line is used as the hybrid coupler 30 (FIG. 1). In the modification to be described below, another coupler is used as the hybrid coupler 30.

FIG. 8 is a schematic plan view of a hybrid coupler 30 used in a radio frequency power amplifier according to a modification of the first embodiment. In the present modification, a branch line coupler is used as the hybrid coupler 30.

The hybrid coupler 30 includes four transmission lines 31A, 31B, 31C, and 31D, each of which is equivalent to a quarter wavelength in length, arranged along the perimeter of a square. As an example, the transmission lines 31A, 31B, 31C, and 31D are arranged clockwise in this order. The characteristic impedance of the transmission lines 31A and 31C is Z₀, and the characteristic impedance of the transmission lines 31B and 31D is Z₀/2^{1/2}.

The connection point between the transmission lines 31A and 31B corresponds to the first port P1, the connection point between the transmission lines 31A and 31D corresponds to the second port P2, the connection point between the transmission lines 31C and 31D corresponds to the third port P3, and the connection point between the transmission lines 31B and 31C corresponds to the fourth port P4.

FIG. 9 is a schematic perspective view of a hybrid coupler 30 used in a radio frequency power amplifier according to another modification of the first embodiment. In the present modification, a parallel plate coupler is used as the hybrid coupler 30.

The hybrid coupler 30 includes rectangular conductive flat plates 32A and 32B facing parallel to each other. One corner portion of the one flat plate 32A corresponds to the first port P1, and the corner portion opposite it corresponds to the fourth port P4. The corner portion of the other flat plate 32B that overlaps the corner portion corresponding to the first port P1 corresponds to the third port P3, and the opposite corner portion in the longitudinal direction corresponds to the second port P2.

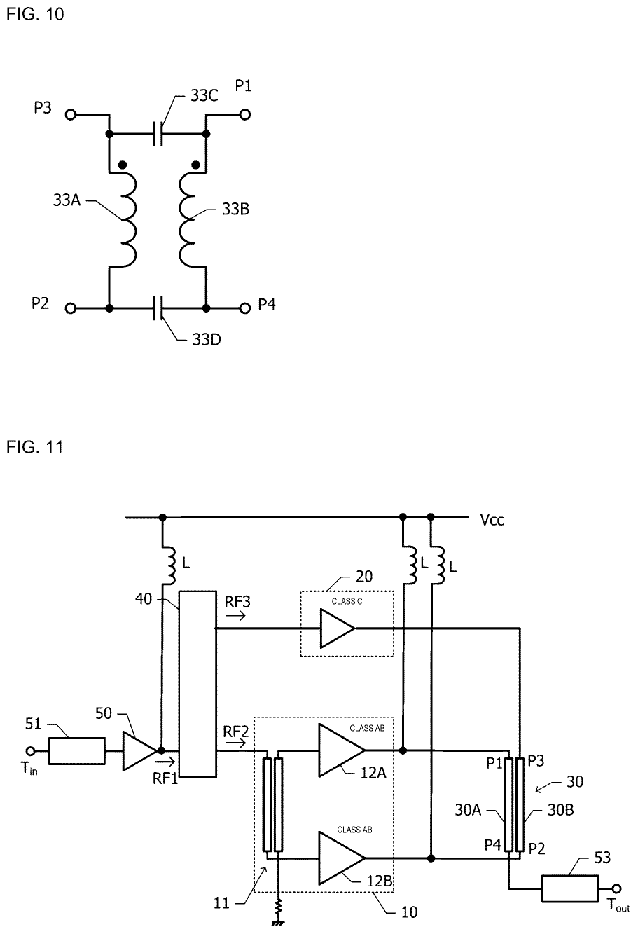

FIG. 10 is an equivalent circuit diagram of a hybrid coupler 30 used in a radio frequency power amplifier according to still another modification of the first embodiment. In the present modification, a lumped-constant coupler is used as the hybrid coupler 30.

The hybrid coupler 30 includes a pair of inductors 33A and 33B that are magnetically coupled to each other and capacitors 33C and 33D. One end of the one inductor 33A corresponds to the third port P3, and the other end thereof corresponds to the second port P2. The end portion of the other inductor 33B on the third port P3 side corresponds to the first port P1, and the opposite end portion thereof corresponds to the fourth port P4. The capacitor 33C is connected between the first port P1 and the third port P3, and the capacitor 33D is connected between the second port P2 and the fourth port P4.

As illustrated in FIGS. 8, 9, and 10, for example, a branch line coupler, a parallel plate coupler, or a lumped-constant coupler can also be used as the hybrid coupler 30.

### Second Embodiment

Next, a radio frequency power amplifier according to a second embodiment will be described with reference to FIG. 11. Descriptions will be omitted for configurations common to the radio frequency power amplifier according to the first embodiment described with reference to FIGS. 1 to 5C.

FIG. 11 is a block diagram of the radio frequency power amplifier according to the second embodiment. In the first embodiment (FIG. 1), the power supply voltage Vcc is supplied to each of the two amplifiers 12A and 12B of the balanced amplifier 10 and the control amplifier 20 via the choke coil L. That is, the respective dedicated power supply lines are provided for the two amplifiers 12A and 12B of the balanced amplifier 10 and the control amplifier 20.

In the radio frequency power amplifier according to the second embodiment, the power supply voltage Vcc is supplied from the output end of the amplifier 12B (output end of the balanced amplifier 10 connected to the second port) to the control amplifier 20 via the sub line 30B of the hybrid coupler 30. There is no dedicated power supply line for the control amplifier 20, and the power supply line for the amplifier 12B is used as part of the power supply line for the control amplifier 20.

Next, the advantageous effect of the second embodiment will be described. In the second embodiment, a dedicated power supply line is not needed for the control amplifier 20. Accordingly, the miniaturization of a device can be achieved.

### Third Embodiment

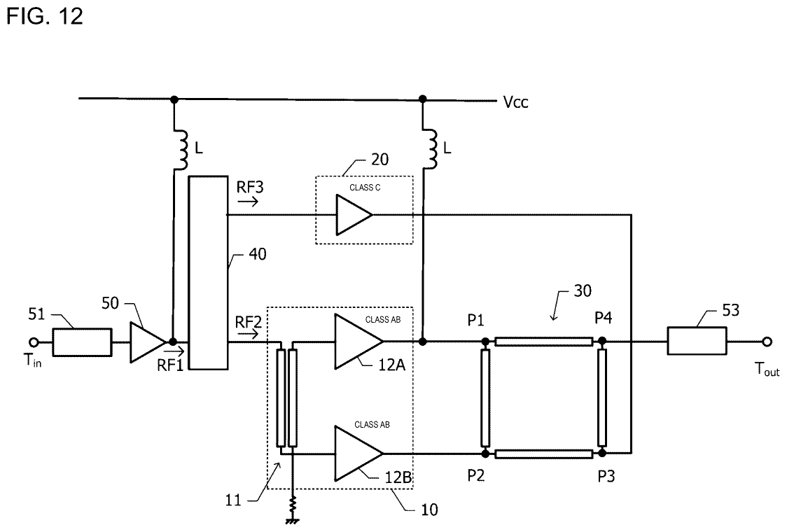

Next, a radio frequency power amplifier according to a third embodiment will be described with reference to FIG. 12. Descriptions will be omitted for configurations common to the radio frequency power amplifier according to the second embodiment described with reference to FIG. 11.

In the second embodiment (FIG. 11), a 3-dB coupler including a coupling transmission line is used as the hybrid coupler 30. In the third embodiment, a branch line coupler is used as the hybrid coupler 30. In the branch line coupler, the first port P1, the second port P2, the third port P3, and the fourth port P4 are all DC short-circuited. The hybrid coupler 30 can therefore be used as part of a power supply line for DC.

In the second embodiment (FIG. 11), the respective dedicated power supply lines are provided for the two amplifiers 12A and 12B of the balanced amplifier 10. In the radio frequency power amplifier according to the third embodiment, the power supply line is provided only for one of the two amplifiers 12A and 12B. For example, the power supply line is provided for the one amplifier 12A, and no dedicated power supply line is provided for the other amplifier 12B.

From the power supply line connected to the one amplifier 12A, the power supply voltage Vcc is supplied to the other amplifier 12B via the first port P1 and the second port P2 of the hybrid coupler 30. From the power supply line connected to the amplifier 12A, the power supply voltage Vcc is supplied to the control amplifier 20 via the hybrid coupler 30.

Next, the advantageous effect of the third embodiment will be described. In the third embodiment, a dedicated power supply line is unnecessary not only for the control amplifier 20 but also for the one amplifier 12B of the balanced amplifier 10. Accordingly, the further miniaturization of a device can be achieved.

### Fourth Embodiment

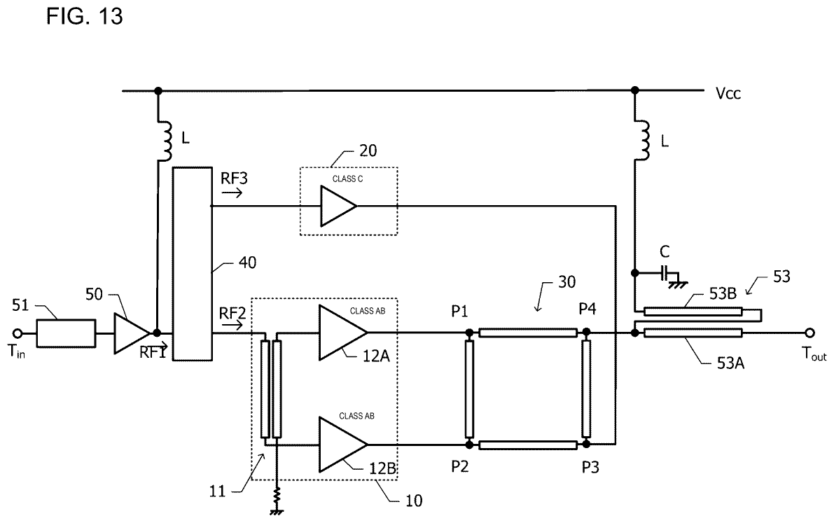

Next, a radio frequency power amplifier according to a fourth embodiment will be described with reference to FIG. 13. Descriptions will be omitted for configurations common to the radio frequency power amplifier according to the first embodiment described with reference to FIGS. 1 to 5C.

FIG. 13 is a block diagram of the radio frequency power amplifier according to the fourth embodiment. In the first embodiment (FIG. 1), the respective dedicated power supply lines are provided for the two amplifiers 12A and 12B of the balanced amplifier 10 and the control amplifier 20.

In the radio frequency power amplifier according to the fourth embodiment, a single power supply line is provided that is shared by three components, that is, the two amplifiers 12A and 12B of the balanced amplifier 10 and the control amplifier 20. A transmission line transformer is used as the impedance matching circuit 53 connected to the fourth port P4 of the hybrid coupler 30. The transmission line transformer includes a main line 53A and a sub line 53B that are electromagnetically coupled to each other.

The input port of the main line 53A is connected to the fourth port P4, and the pass-through port thereof is connected to the output terminal Tout. The isolation port of the sub line 53B is connected to the input port of the main line 53A. The coupling port of the sub line 53B is grounded via a capacitor C in terms of radio frequency and is connected to the power supply line for the power supply voltage Vcc via the choke coil L in terms of direct current.

The power supply voltage Vcc is supplied to the two amplifiers 12A and 12B of the balanced amplifier 10 and the control amplifier 20 via the sub line 53B of the impedance matching circuit 53 and the hybrid coupler 30.

Next, the advantageous effect of the fourth embodiment will be described. In the fourth embodiment, the two amplifiers 12A and 12B of the balanced amplifier 10 and the control amplifier 20 share part of the power supply line. Accordingly, the miniaturization of a device can be achieved.

The radio frequency power amplifier according to the first embodiment can achieve high efficiency without the insertion of an impedance matching circuit between the output end of the control amplifier 20 and the third port P3 of the hybrid coupler 30, even when operated with a single power supply voltage. Accordingly, like in the second, third, and fourth embodiments, the power supply line can be shared by at least two of the two amplifiers 12A and 12B of the balanced amplifier 10 and the control amplifier 20.

### Fifth Embodiment

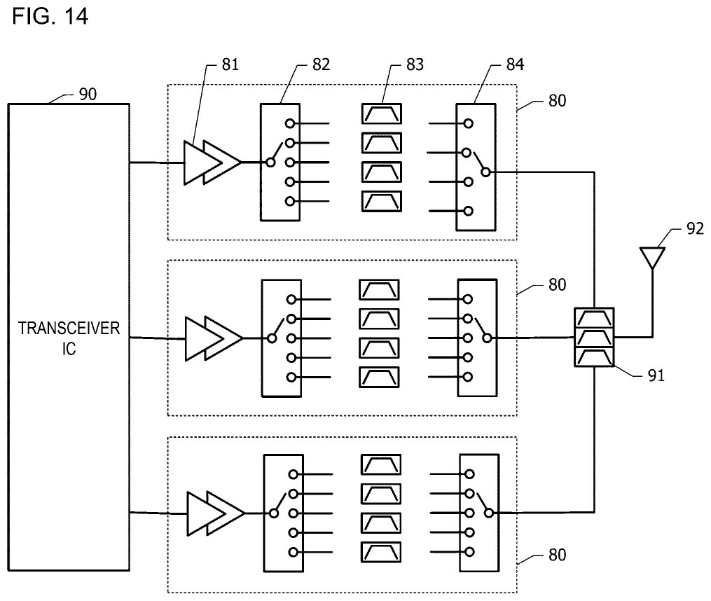

Next, a communication device according to a fifth embodiment will be described with reference to FIG. 14. FIG. 14 is a block diagram of the communication device according to the fifth embodiment. The communication device according to the fifth embodiment includes a transceiver IC 90, a plurality of transmission systems 80, a multiplexer 91, and an antenna 92. Each of the multiple transmission systems 80 includes a radio frequency power amplifier 81, a first switch 82, a plurality of filter circuits 83, and a second switch 84. A radio frequency power amplifier according to the first, second, third, or fourth embodiment is used as the radio frequency power amplifier 81.

Radio frequency signals to be transmitted are inputted from the transceiver IC 90 to the respective radio frequency power amplifiers 81 in the multiple transmission systems 80. The radio frequency signal amplified by the radio frequency power amplifier 81 is inputted to the one filter circuit 83 selected by the first switch 82. The radio frequency signal that has passed through the filter circuit 83 is transmitted to the antenna 92 via the second switch 84 and the multiplexer 91.

Next, the advantageous effect of the fifth embodiment will be described. In the fifth embodiment, a radio frequency power amplifier according to the first, second, third, or fourth embodiment is used as the radio frequency power amplifier 81. Accordingly, a high-efficiency operation can be achieved with a single power supply voltage, and the degradation of broadband characteristics can be suppressed.

The above embodiments are merely illustrative, and the configurations described in the different embodiments can be partially exchanged or combined. The same advantageous effects obtained from the same configuration are not mentioned in each of the multiple embodiments. The present disclosure is not limited to the above embodiments. It should be obvious to those skilled in the art that various changes, improvements, combinations, etc. are possible.

Based on the above embodiments described in this specification, the following disclosure is provided.

<1> A radio frequency power amplifier comprising: a hybrid coupler having a first port, a second port, a third port, and a fourth port to which a load is connected; an input signal distributor configured to distribute a first input signal that is a radio frequency signal into a second input signal and a third input signal; a balanced amplifier configured to receive the second input signal and output two amplified radio frequency signals with a phase difference of 90° from each other from two output ends, one of which is coupled to the first port and another one of which is coupled to the second port; and a control amplifier configured to amplify the third input signal and output the amplified third input signal from an output end that is coupled to the third port without any circuit component affecting impedance matching disposed in between, wherein a power supply voltage in common is supplied to the balanced amplifier and the control amplifier, wherein a voltage level of the first input signal at a rise of a current outputted from the control amplifier is higher than a voltage level of the first input signal at a rise of a current outputted from the balanced amplifier, and wherein the hybrid coupler changes a load impedance of the balanced amplifier coupled to the first port and the second port in accordance with a current level of a radio frequency signal inputted to the third port from the control amplifier.

<2> The radio frequency power amplifier according to <1>, wherein a load impedance of the balanced amplifier when a current from the control amplifier is not rising is equal to a load impedance of the control amplifier when the current from the control amplifier is rising.

<3> The radio frequency power amplifier according to <1> or <2>, wherein the balanced amplifier, the control amplifier, and the hybrid coupler are configured such that when a voltage level of the first input signal is increased, a voltage level at the output ends of the balanced amplifier remains constant after a rise of a current from the control amplifier, and wherein, when a maximum value of the voltage level of the first input signal is 1, the voltage level of the first input signal at the rise of the current from the control amplifier is 0.37 or more and 0.45 or less.

<4> The radio frequency power amplifier according to any one of <1> to <3>, wherein the hybrid coupler includes a coupling transmission line including a main line with the first port and the fourth port at both ends and a sub line with the third port and the second port at both ends, and wherein the power supply voltage is supplied from the output end of the balanced amplifier connected to the second port to the control amplifier via the sub line of the hybrid coupler.

<5> The radio frequency power amplifier according to any one of <1> to <3>, wherein the hybrid coupler is a branch line coupler, and wherein the power supply voltage is supplied from an output end of one amplifier in the balanced amplifier to another amplifier in the balanced amplifier and the control amplifier via the branch line coupler.

<6> The radio frequency power amplifier according to any one of <1> to <3>, further comprising a transmission line transformer disposed between the fourth port and the load, wherein the hybrid coupler is a branch line coupler, and wherein the power supply voltage is supplied to the balanced amplifier and the control amplifier via the transmission line transformer and the hybrid coupler.

What is claimed is:

1. A radio frequency power amplifier comprising:
a hybrid coupler having a first port, a second port, a third port, and a fourth port to which a load is connected;
an input signal distributor configured to distribute a first input signal that is a radio frequency signal into a second input signal and a third input signal;
a balanced amplifier configured to receive the second input signal and to output two amplified radio frequency signals with a phase difference of 90° from each other from two output ends, one of the two output ends being coupled to the first port and another one of the two output ends being coupled to the second port; and
a control amplifier configured to amplify the third input signal and to output the amplified third input signal from an output end that is coupled to the third port without any circuit component affecting impedance matching disposed in between,
wherein a power supply voltage is supplied to the balanced amplifier and to the control amplifier, the power supply voltage being common to the balanced amplifier and the control amplifier,
wherein a voltage level of the first input signal at a rise of a current output from the control amplifier is higher than a voltage level of the first input signal at a rise of a current output from the balanced amplifier, and
wherein the hybrid coupler is configured to change a load impedance of the balanced amplifier coupled to the first port and the second port in accordance with a current level of a radio frequency signal input to the third port from the control amplifier.

2. The radio frequency power amplifier according to claim 1, wherein a load impedance of the balanced amplifier when a current from the control amplifier is not rising is equal to a load impedance of the control amplifier when the current from the control amplifier is rising.

3. The radio frequency power amplifier according to claim 1,
wherein when a voltage level of the first input signal is increased, a voltage level at the output ends of the balanced amplifier remains constant after a rise of a current from the control amplifier, and
wherein, when a maximum value of the voltage level of the first input signal is 1, the voltage level of the first input signal at the rise of the current from the control amplifier is equal to or greater than 0.37 and equal to or less than 0.45.

4. The radio frequency power amplifier according to claim 2,
wherein when a voltage level of the first input signal is increased, a voltage level at the output ends of the balanced amplifier remains constant after a rise of a current from the control amplifier, and
wherein, when a maximum value of the voltage level of the first input signal is 1, the voltage level of the first input signal at the rise of the current from the control amplifier is equal to or greater than 0.37 and equal to or less than 0.45.

5. The radio frequency power amplifier according to claim 1,
wherein the hybrid coupler comprises a coupling transmission line comprising a main line with the first port and the fourth port at opposite ends thereof, and a sub line with the third port and the second port at opposite ends thereof, and
wherein the power supply voltage is supplied from the output end of the balanced amplifier connected to the second port to the control amplifier via the sub line of the hybrid coupler.

6. The radio frequency power amplifier according to claim 2,
wherein the hybrid coupler comprises a coupling transmission line comprising a main line with the first port and the fourth port at opposite ends thereof, and a sub line with the third port and the second port at opposite ends thereof, and
wherein the power supply voltage is supplied from the output end of the balanced amplifier connected to the second port to the control amplifier via the sub line of the hybrid coupler.

7. The radio frequency power amplifier according to claim 1,
wherein the hybrid coupler is a branch line coupler, and
wherein the power supply voltage is supplied from an output end of one amplifier in the balanced amplifier to another amplifier in the balanced amplifier and to the control amplifier via the branch line coupler.

8. The radio frequency power amplifier according to claim 2,
wherein the hybrid coupler is a branch line coupler, and
wherein the power supply voltage is supplied from an output end of one amplifier in the balanced amplifier to another amplifier in the balanced amplifier and to the control amplifier via the branch line coupler.

9. The radio frequency power amplifier according to claim 1, further comprising a transmission line transformer between the fourth port and the load,
wherein the hybrid coupler is a branch line coupler, and
wherein the power supply voltage is supplied to the balanced amplifier and to the control amplifier via the transmission line transformer and the hybrid coupler.

10. The radio frequency power amplifier according to claim 2, further comprising a transmission line transformer between the fourth port and the load,
wherein the hybrid coupler is a branch line coupler, and
wherein the power supply voltage is supplied to the balanced amplifier and to the control amplifier via the transmission line transformer and the hybrid coupler.
